(19) United States
(12) Patent Application Publication
(10) Pub. No.: US 2005/0120955 A1
(43) Pub. Date: Jun. 9, 2005

(54) Film forming apparatus

(75) Inventors: Hideaki Yamasaki, Nirasaki-shi (JP); Yumiko Kawano, Nirasaki-shi (JP); Norihiko Yamamoto, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/030,899

(22) Filed: Jan. 10, 2005

Related U.S. Application Data
(63) Continuation of application No. PCT/JP03/08800, filed on Jul. 10, 2003.

(30) Foreign Application Priority Data
Jul. 10, 2002 (JP) 2002-201533

(51) Int. Cl. C23C 16/00

(52) U.S. Cl. 118/715

(57) ABSTRACT

A film forming unit includes a source vessel for receiving a raw material from which source gas is produced, a processing vessel for applying a film forming process on a semiconductor substrate, a source supply line for supplying the source gas from the source vessel to the processing vessel, a gas exhaust line for exhausting gas from the processing vessel, having a vacuum pump system structured by a turbo molecular pump and a dry pump, and a pre-flow line branching off from the source supply line while bypassing the processing vessel and the turbo molecular pump, and joining to the gas exhaust line. Moreover, the source supply line includes piping having an inner diameter greater than 6.4 mm, and a turbo molecular pump is provided in the pre-flow line.

This application is a Continuation Application of PCT International Application No. PCT/JP03/08800 filed on Jul. 10, 2003, which designated the United States.

### FIELD OF THE INVENTION

The present invention relates to a semiconductor manufacturing apparatus; and, more particularly, to a semiconductor manufacturing apparatus capable of enhancing a film forming rate during a film forming process employing a low vapor pressure source material.

### BACKGROUND OF THE INVENTION

With the recent increase in the size of semiconductor substrates, the semiconductor manufacturing apparatus tends to perform a single substrate processing, rather than a batch processing used to simultaneously treat a plurality of semiconductor substrates. In order to improve the processing efficiency or throughput of the apparatus which performs the single substrate processing, the processing time per substrate need be shortened. Accordingly, attempts have been made to increase the flow rate of a source gas supplied to a processing vessel of the semiconductor manufacturing apparatus, to thereby increase the film forming rate (deposition rate) and reduce the processing time.

Further, in case of such a single substrate processing apparatus, the flow rate of the source gas need be stabilized, before the source gas is supplied to the processing vessel of the semiconductor manufacturing apparatus. Therefore, as shown in FIG. 5, a source supply line 30′ which supplies a source gas to a processing vessel 120′ of a conventional semiconductor manufacturing apparatus is normally provided with a pre-flow line 33′ which bypasses the processing vessel 120′. In such a semiconductor manufacturing apparatus, the source gas, before being introduced into the processing vessel 120′, is fed to the pre-flow line 33′ by switching a valve 26′; and then, after stabilizing the flow rate thereof, the source gas is supplied to the processing vessel 120′ by another switching operation of the valve 26′.

In order to gasify a solid or a liquid source material and supply the source gas to the semiconductor manufacturing apparatus at room temperature, the liquid or the solid source material is typically heated or, alternatively, the liquid source material itself or the solid source material dissolved in a solvent is supplied to a vaporizer, and then the source material vaporized at the vaporizer is provided as the source gas into the processing vessel.

However, in case of a film forming process for the formation of high-k dielectric films or ferroelectric films, e.g., Ru films or W films, recently employed in semiconductor devices, the heating of the source material may not produce a source gas in a sufficient quantity due to its low vapor pressure. In such a case, the source gas is supplied to the processing vessel 120′ with the aid of a carrier gas. In order to increase the flow rate of the source gas when employing such a low vapor pressure source material, it may be required to increase the vapor pressure by heating the source material at a higher temperature and facilitate the vaporization of the source material by way of depressurizing the source vessel. As illustrated in FIG. 5, therefore, a turbo molecular pump (TMP) 14′ and a dry pump (DP) 16′ are provided at a gas exhaust line 32′ of the conventional semiconductor manufacturing apparatus to depressurize the source vessel 10′ and the processing vessel 120′.

However, as described above, even in case the source vessel 10′ and the like are depressurized by using the turbo molecular pump 14′ and the like, the capacity to increase the flow rate of the source gas is still restricted in case of using a low vapor pressure source material in addition to the small inner diameter, e.g., ¼ inch, of the piping generally used in the art. Moreover, due to the small piping diameter, the pressure losses at the source supply line 30′ may hinder an efficient depressurization of the source vessel 10′ and, consequently, an efficient vaporization of the source material.

Furthermore, in the prior art equipment, since the pre-flow line 33′ bypasses the turbo molecular pump 14′ as shown in FIG. 5 and the piping diameter of the pre-flow line 33′ is generally smaller than or equal to that of the source supply line 30′, the pressure in the source vessel 10′ while the source gas is flowing through the pre-flow line 33′ may be different from the pressure in the source vessel 10′ when the film forming process is performed. Thus, even in case the source gas is made to flow through the pre-flow line 33′ before the film forming process to stabilize the flow rate thereof, there still remains a problem that the flow rate thereof is not actually stabilized.

### SUMMARY OF THE INVENTION

It is, therefore, a primary object of the present invention to provide a film forming apparatus capable of substantially improving the film forming rate by increasing the flow rate of a source gas supplied to a processing vessel of a semiconductor manufacturing device.

It is another object of the present invention to provide a film forming apparatus including a pre-flow line capable of substantially stabilizing the flow rate of a source gas before conducting a film forming process.

In accordance with a first aspect of the present invention, there is provided a film forming apparatus including: a source vessel for accommodating a source material used to generate a source gas; a film forming chamber wherein a film forming process is performed on a semiconductor substrate; a source supply channel for supplying the source gas from the source vessel to the film forming chamber; and a gas exhaust channel, having a vacuum pump system, for exhausting the film forming chamber, wherein the source supply channel includes a piping with an inner diameter of greater than 6.4 mm.

In accordance with a second aspect of the present invention, there is provided a film forming apparatus including: a source vessel for accommodating a source material used to generate a source gas; a film forming chamber wherein a film forming process is performed on a semiconductor substrate; a source supply channel for supplying the source gas from the source vessel to the film forming chamber; a gas exhaust channel, having a vacuum pump system comprised of a turbo molecular pump and a dry pump, for exhausting the film forming chamber; and a pre-flow channel branching off from the source supply channel and joining to the gas exhaust channel, wherein a second turbo molecular pump is provided at the pre-flow channel.

In the second aspect of the present invention, alternatively, the pre-flow channel may be made to join the gas exhaust channel at an upstream of the turbo molecular pump. In this case, since the vacuum pump system of the gas exhaust channel can be used while the pre-flow channel is activated, it is possible to reduce the difference between the pressure in the source vessel during the activation of the pre-flow channel and the pressure in the source vessel during the film forming process, without having to provide the second turbo molecular pump at the pre-flow channel.

In accordance with a third aspect of the present invention, there is provided a film forming apparatus including: a source vessel for accommodating a source material used to generate a source gas; a film forming chamber wherein a film forming process is performed on a semiconductor substrate; a source supply channel for supplying the source gas from the source vessel to the film forming chamber; a gas exhaust channel, having a vacuum pump system comprised of a turbo molecular pump and a dry pump, for exhausting the film forming chamber; and a pre-flow channel branching off from the source supply channel and joining to the gas exhaust channel, wherein the piping diameter of the pre-flow channel is enlarged to reduce a pressure difference between the pressure in the source vessel during the activation of the pre-flow line and the pressure in the source vessel during the film forming process.

In each of the afore-mentioned aspects of the present invention, valves disposed at the pre-flow channel and/or the source supply channel preferably have a conductance Cv which is greater than or equal to 1.5. Especially, each of the valves disposed at the pre-flow channel and the source supply channel preferably has a conductance Cv greater than or equal to 1.5. Further, the source supply channel preferably includes a piping having an inner diameter of greater than 6.4 mm over a range of, at least, 80% of the entire length thereof. The source supply channel is designed to maintain the difference between the pressure in the source vessel and that in the film forming chamber during the film forming process, to be smaller than 2000 Pa. The source supply channel preferably includes a piping having an inner diameter of greater than or equal to about 16 mm. A source gas, generated from a source material having a vapor pressure lower than 133 Pa at a vaporization temperature, may flow through the source supply channel. An exemplary source material thereof is W(CO)₆. The pressure in the film forming chamber is preferably maintained to be lower than 665 Pa during the film forming process.

### BRIEF DESCRIPTION OF THE DRAWINGS

The objects, features and advantages of the present invention will become apparent from the following detailed description of the preferred embodiments with reference to the accompanying drawings, wherein:

FIG. 1 shows schematically the configuration of a CVD film forming unit 100;

FIG. 2 depicts schematically the configuration of a source supply unit 200 in accordance with a first preferred embodiment of the present invention;

FIGS. 3A and 3B provide schematically the configurations of a source supply unit 200 in accordance with a second preferred embodiment of the present invention;

FIG. 4 presents a table for comparing the differences between the pressure in a processing vessel and that in a source vessel, while varying a piping diameter; and

FIG. 5 represents schematically the configuration of a conventional semiconductor manufacturing apparatus.

### DETAILED DESCRIPTION OF THE PREFERRED EMBODIMENTS

The preferred embodiments of the present invention will now be described with reference to the accompanying drawings.

[A First Preferred Embodiment]

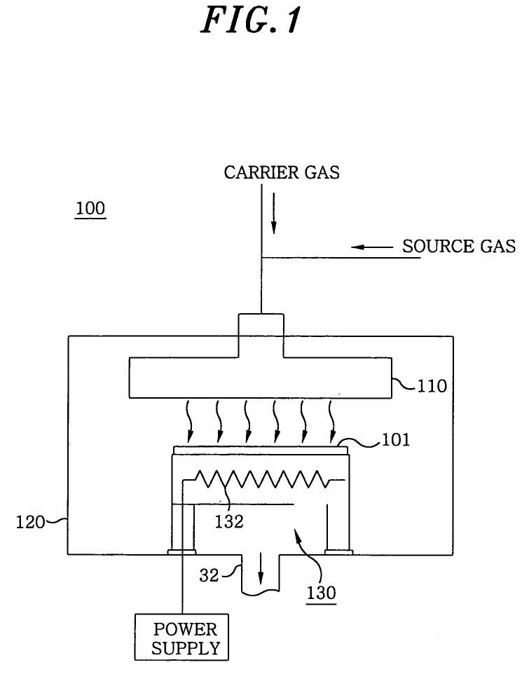

FIG. 1 is a sectional view showing schematically the configuration of a CVD film forming unit 100 in accordance with a first preferred embodiment of the present invention.

As shown in FIG. 1, the CVD film forming unit 100 includes a processing vessel 120 of an airtight structure; a mounting table 130, disposed at a central portion of the processing vessel 120, for supporting a semiconductor substrate 101 and burying therein a heating device 132 connected to a power supply; a shower head 110, so disposed as to face the mounting table 130, for introducing a gas, which is supplied from a source supply line 30 (to be described later), into the processing vessel 120; a gate valve (not shown), disposed at a sidewall of the processing vessel 120, for loading/unloading the semiconductor substrate 101 into/from the processing vessel 120; and a gas exhaust line 32, having a vacuum pump system, for exhausting the processing vessel 120.

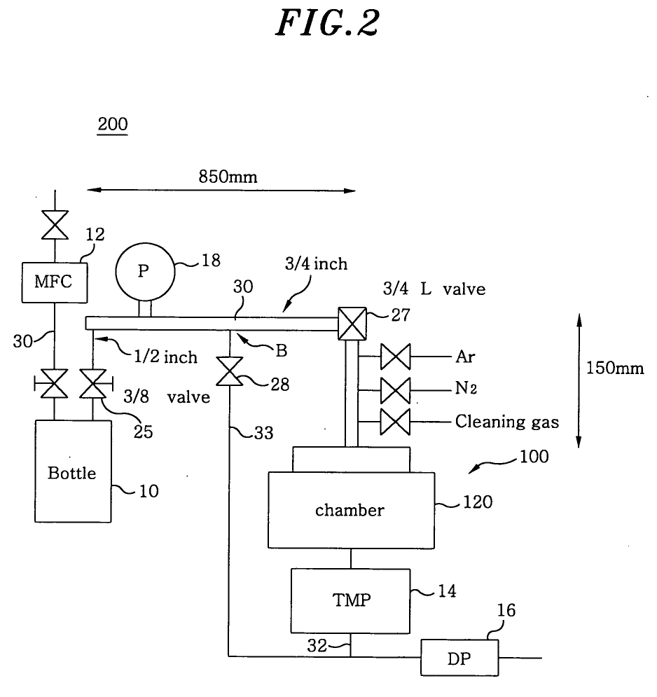

FIG. 2 illustrates the configuration of a source supply unit 200 in accordance with the first preferred embodiment of the present invention.

Referring to FIG. 2, a carrier gas comprised of a inert gas such as Ar, Kr, N₂ and He is supplied to the source vessel 10 via a mass flow controller (MFC) 12. The mass flow controller 12 controls the flow rate of the carrier gas supplied to the source vessel 10. The source vessel 10 accommodates therein a liquid source material or solid source material which is to be used for the film forming process. A source gas is generated by vaporizing the source material by a bubbling process or the like in the source vessel 10 and then transferred to the CVD film forming unit 100 by the carrier gas through the source supply line 30. Further, near an outlet of the source vessel 10 of the source supply line 30 is provided a pressure gauge 18 for detecting the pressure in the source vessel 10.

Provided at the source supply line 30 is a pre-flow line 33 which bypasses the CVD film forming unit 100 in the downstream of the source vessel 10. A carrier gas containing the source gas (hereinafter, referred to as “mixed gas”) is supplied from the source supply line 30 to the pre-flow line 33. The mixed gas is selectively supplied to the pre-flow line 33 or the source supply line 30 which passes through the CVD film forming unit 100, by opening or closing valves 28 and 27.

Moreover, the pre-flow line 33 serves as a gas flow path for stabilizing the flow rate of the mixed gas supplied to the CVD film forming unit 100 during the film forming process. For such purpose, the mixed gas is supplied to the pre-flow line 33 before a single substrate processing is executed one by one on the semiconductor substrate 101.

Gas lines are connected via valves to the source supply line 30 which extends from a junction node B, at which the pre-flow line 33 diverges, to the CVD film forming unit 100. The gas lines supply various gases to be required during the film forming process and a cleaning gas for cleaning the processing vessel 120 after executing the film forming process and the like. These gases may be introduced into the processing vessel 120 while the mixed gas is flowing through the pre-flow line 33 (i.e., while the valve 28 is open and the valve 27 is closed).

A turbo molecular pump (TMP) 14 is provided at a gas exhaust line 32 for evacuating the reaction gas and the like from the CVD film forming unit 100. A dry pump (DP) 16 is provided at a downstream of the turbo molecular pump 14. These pumps 14 and 16 maintain the internal pressure of the processing vessel 120 under a certain vacuum level. The turbo molecular pump 14, together with the dry pump 16, is able to set the pressure in the processing vessel 120 to be at a high vacuum level, i.e., smaller than or equal to, e.g., 1 Torr (133 Pa). Thus, the turbo molecular pump 14 and the dry pump 16 are especially needed in case a low vapor pressure source material, such as dimethylaluminumhydride (DMAH), biscyclopentadienyllutenium (RuCp₂), hexacarbonyltungsten (W(CO)₆) or the like, is used for the film forming process.

The pre-flow line 33 joins to the gas exhaust line 32 at an upstream of the dry pump 16. Therefore, while the mixed gas is flowing through the pre-flow line 33, the source vessel 10 is depressurized by the dry pump 16. During the film forming process, however, the source vessel 10 is depressurized by the dry pump 16 and the turbo molecular pump 14.

Meanwhile, in order to improve the film forming rate, there is a need to increase the flow rate of the source gas, which is contained in the mixed gas and supplied to the CVD film forming unit 100. The flow rate of the source gas can be increased by increasing the flow rate of the carrier gas and the temperature of the source vessel 10. On the other hand, the flow rate of the source gas decreases, as the pressure in the source vessel 10 increases. Accordingly, in order to increase the flow rate of the source gas, the pressure in the source vessel 10 is required to be as low as possible.

As described above, the source vessel 10 is depressurized by the turbo molecular pump 14 and the like via the processing vessel 120 and the source supply line 30. However, in order to achieve a high efficiency of the depressurization and, at the same time, to increase the flow rate of the source gas, pressure losses should be reduced as much as possible at the flow path which extends from the turbo molecular pump 14 to the source vessel 10.

Meanwhile, since the flow rate of the source gas is in proportion to that of the carrier gas, it is possible to increase the flow rate of the carrier gas in order to increase that of the source gas. However, if the source supply line 30 has a piping diameter of ¼ inch which is generally employed in the art, the conductance of the source supply line 30 becomes so small that the capacity to increase the flow rate of the carrier gas (and that of the source gas) by the above-mentioned depressurization is limited.

High-k dielectric films or ferroelectric films, e.g., Ru films or W films, recently employed in semiconductor devices, is formed by employing low vapor pressure source materials. For example, W(CO)₆ that can be used for forming a W film has a vapor pressure of 3.99 Pa (0.03 Torr) at 25 C; 6.65 Pa (0.05 Torr) at 30 C; and 33.25 Pa (0.25 Torr) at 45 C. However, in case such a low vapor pressure source material is used, it is very difficult to increase the flow rate of the source gas.

Accordingly, in the first embodiment of the present invention, the source supply line 30 is set to have a piping diameter greater than ¼ inch (about 6.4 mm), e.g., 1/2 inch (about 13 mm) or ¾ inch (about 19 mm), in order to increase the flow rate of the carrier gas (and that of the source gas accompanied by the carrier gas). The source supply line 30 having the piping diameter greater than ¼ inch preferably covers from the source vessel 10 to the processing vessel 120. In other words, the source supply line 30, through which the source gas flows, is preferably comprised of a piping having an inner diameter which is constant until it reaches the processing vessel 120.

However, if the length from the source vessel 10 to the processing vessel 120 is short, the source supply line 30 can be comprised of a piping having different inner diameters. For instance, referring to FIG. 2, a piping having an inner diameter of ½ inch may be used within a short range from an outlet of the source vessel 10 while a piping having an inner diameter of ¾ inch is used for a range covering the major parts from the source vessel 10 to the processing vessel 120.

Further, from such a point of view as described above, valves 25 and 27 that may be disposed at the source supply line 30 preferably have diameters equal to the inner diameter of the source supply line 30. However, like as the valve 25 illustrated in FIG. 2, the valves 25 and 27 may have the inner diameters of ⅜ inch which is used extensively in case the source supply line 30 has the inner diameter of ½ inch. Furthermore, the entire length of the source supply line 30 may be set as short as possible in order to reduce the energy loss of the mixed gas, to thereby increase the flow rate thereof. For example, the source supply line 30 illustrated in FIG. 2 is comprised of a piping having the inner diameter of ¾ inch, which has an entire length of 1000 mm, except a portion of piping having the inner diameter of ½ inch.

Although the source supply unit 200 in accordance with the first embodiment has one source supply line 30, a plurality of source supply lines may be provided in case multiple types of source gases are employed. In such case, each of the source supply lines for transferring the low vapor pressure source material may be comprised of a piping having an inner diameter of greater than ¼ inch; however, each of the source supply lines for transferring a relatively high vapor pressure source material may be generally comprised of a piping having an inner diameter of ¼ inch.

In accordance with the first embodiment of the present invention, the flow rate of a fluid flowing through a piping increases in proportion to the fourth power of the inner diameter of the piping, so that the flow rate of the source gas introduced into the processing vessel 120 can be drastically increased. Further, since the pressure loss of the mixed gas at the source supply line 30 is reduced as the piping diameter of the source supply line 30 increases, the workload of the turbo molecular pump 14, which functions to reduce the pressure in the source vessel 10, can be lowered. Furthermore, in case the pressure loss at the source supply line 30 is small, the flow rate of the source gas introduced into the processing vessel 120 can be further increased.

In case the film forming process is performed by using a low vapor pressure source material, such as W(CO)₆, the pressure in the source vessel 10 may be preferably maintained at a high vacuum level of, e.g., smaller than or equal to 2 Torr (266 Pa) by using the turbo molecular pump 14 in order to increase the flow rate of the source gas.

However, while the pre-flow line 33 is activated, it may not be possible to maintain the pressure in the source vessel 10 at such a low pressure level using the dry pump 16 alone. Therefore, even in case the mixed gas flows through the pre-flow line before conducting the film forming process, the pressure in the source vessel 10 may vary by performing a switching of a flow path for the film forming process, resulting in a fluctuation in the flow rate of the source gas during the film forming process.

As will be described next, a source supply unit 200 provided in accordance with a second preferred embodiment of the present invention to be described in the following, however, solves the aforementioned drawbacks by improving or modifying the pre-flow line 33 of the source supply unit 200 in accordance with the first embodiment of the present invention.

[A Second Preferred Embodiment]

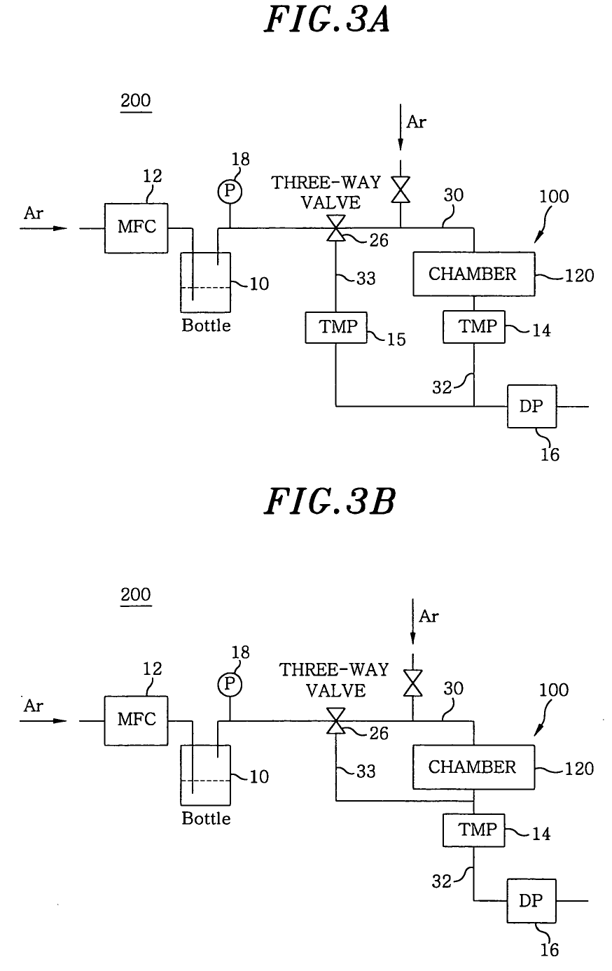

FIG. 3A illustrates the configuration of the source supply unit 200 in accordance with the second preferred embodiment of the present invention. Referring to FIG. 3A, a second turbo molecular pump 15 is disposed at the pre-flow line 33 of the source supply unit 200 in accordance with the second embodiment of the present invention. Thus, while the mixed gas is flowing through the pre-flow line 33 (while the pre-flow line 33 is activated), the source vessel 10 is depressurized by the dry pump 16 and the second turbo molecular pump 15. During the film forming process, on the other hand, the source vessel 10 is depressurized by the dry pump 16 and the turbo molecular pump 14.

As a result, the difference between the pressure in the source vessel 10 while the mixed gas is flowing through the pre-flow line 33 and that in the source vessel 10 when the film forming process is performed is reduced. In other words, the pressure in the source vessel 10 can be maintained at a high vacuum level of, e.g., smaller than or equal to 2 Torr (266 Pa) during the film forming process using a low vapor pressure source material, such as W(CO)₆, and at the same time, the high vacuum level in the source vessel 10 can also be achieved by the second turbo molecular pump 15 while activating the pre-flow line 33. Accordingly, the pressure variation in the source vessel 10, which causes a fluctuation in the flow rate of the source gas, can be suppressed, so that the film forming process can be stably performed without the fluctuation in the flow rate of the source gas.

Moreover, from such a point of view as described above, the piping diameter of the pre-flow line 33 may be preferably selected to be equal to or greater than that of the source supply line 30 in order to reduce the difference between the pressure in the source vessel 10 when the film forming process is performed and that in the source vessel 10 while the pre-flow line is activated. By adjusting the disposed position of the second turbo molecular pump 15 at the pre-flow line 33, the pressure in the source vessel 10 while the mixed gas is flowing through the pre-flow line 33 may be made approximately equal to that in the source vessel 10 when the film-forming process is performed. Accordingly, the flow rate of the source gas while the pre-flow line 33 is activated can be approximately equal to that of the source gas when the film forming process is performed.

In accordance with the second embodiment of the present invention, it is possible to substantially reduce or eliminate the difference between the flow rate of the source gas while the pre-flow line 33 is activated and that of the source gas introduced into the processing vessel 120. Therefore, an amount of the fluctuation in the flow rate of the source gas can be kept very small while a flow path is switched from the pre-flow line 33 to the source supply line 30 by a three-way valve 26, so that the film forming process can be stably performed.

FIG. 3B provides a modified version of the source supply unit 200 provided in accordance with the second embodiment of the present invention. In the configuration depicted in FIG. 3B, the second turbo molecular pump 15 is not provided at the pre-flow line 33. Instead, the pre-flow line 33 joins to the gas exhaust line 32 at an upstream of the turbo molecular pump 14. In such configuration, in case the pre-flow line 33 is activated, the source vessel 10 is depressurized by the dry pump 16 and the turbo molecular pump 14, like the case of the film forming process.

Therefore, in accordance with the modified embodiment, it is possible to substantially reduce the difference between the flow rate of the source gas while the pre-flow line 33 is activated and that of the source gas introduced into the processing vessel 120. Accordingly, the fluctuation in the flow rate of the source gas is very small while switching a flow path from the pre-flow line 33 to the source supply line 30, so that the film forming process can be stably performed without the fluctuation in the flow rate of the source gas during the film forming process.

Further, in this modified embodiment, in order to minimize the fluctuation in the flow rate of the source gas while a flow path is switched by the three-way valve 26, the electric power to the turbo molecular pump 14 disposed at the gas exhaust line 32 may be adjusted and controlled. Furthermore, the piping diameter of the pre-flow line 33 may be equal to or greater than that of the source supply line 30 so as to reduce the difference between the pressure in the source vessel 10 when the film forming process is performed and that in the source vessel 10 while the pre-flow line is activated.

Moreover, in the second embodiment of the present invention, the valves 28 and 27 provided in the first embodiment may be employed instead of the three-way valve 26. In addition, both in the first and the second embodiments, each of the valves 25, 26 and 27 provided at the source supply line 30 and the pre-flow line 33 (i.e., each valve provided at a flow path extending from the source vessel 10 to the turbo molecular pump) preferably has a conductance Cv of greater than or equal to 1.5. Accordingly, the pressure loss in each valve is reduced so that the aforementioned effects can be further enhanced.

Herein, the Cv of a valve is defined to be a value calculated based on the equation of Cv=Qg/406×{Gg(273+t)/(P₁−P₂)P₂}^{1/2} which applies in case the absolute pressure P₁[kgf·cm³abs] on a first side (i.e., the side near the source vessel 10) is smaller than twice the absolute pressure P₂[kgf·cm³abs] on a second side (i.e., the side near the processing vessel 120), i.e., P₁<2P₂, and that of Cv=Qg/203 P₁×{Gg(273+t)}^{1/2} which applies in case P₁ is greater than or equal to 2P₂, i.e., P₁≧2P₂. Further, in the above-described equations, t[° C.], Qg[Nm²/h] and Gg indicate a gas temperature, the flow rate of a gas in the standard state (15° C., 760 mmHgabs) and the specific gravity of a gas in case that of air being set to be 1, respectively.

### [EXAMPLE 1]

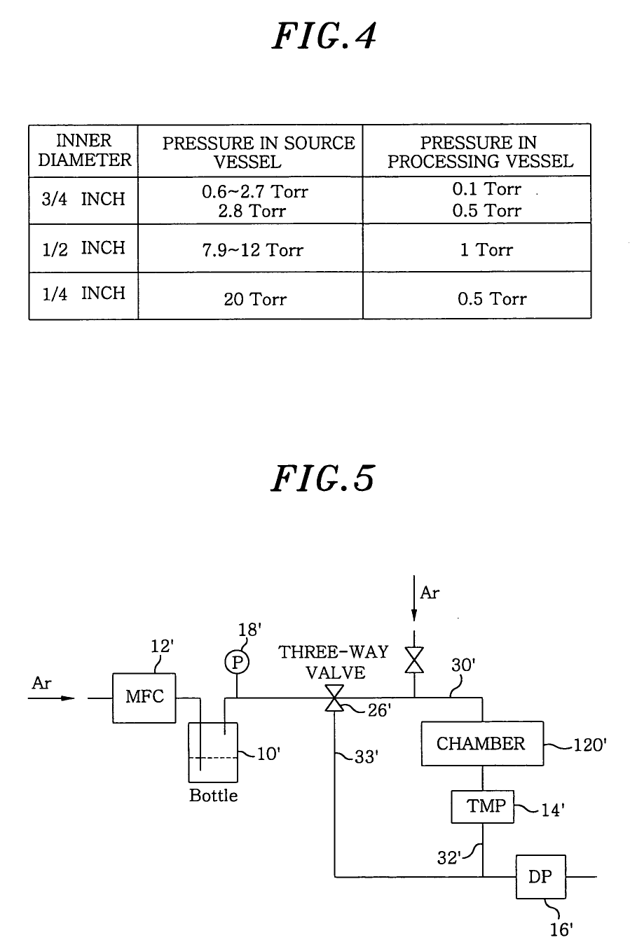

The results shown in FIG. 4 represent the differences between the pressure in the processing vessel 120 and that in the source vessel 10 obtained as a function of the piping diameter in accordance with the first preferred embodiment.

As shown in FIG. 4, in case a piping having the inner diameter of ¾ inch was employed for the source supply line 30 and the pressure in the processing vessel 120 was set to be 13.3 Pa (0.1 Torr), the pressure in the source vessel 10 was depressurized to 79.8 Pa (0.6 Torr).

Therefore, it can be seen that even in case a low vapor pressure source material, such as W(CO)₆ with a vapor pressure of 3.99 Pa (0.03 Torr) at 25° C. and that of 33.25 Pa (0.25 Torr) at 45° C. is employed, the pressure in the processing vessel 120 can be sufficiently depressurized, so that a source gas of a sufficient flow rate can be obtained.

In the meantime, in case a piping having the inner diameter of ¼ inch was employed and the pressure in the processing vessel 120 was set to be 66.6 Pa (0.5 Torr), the pressure in the source vessel 10 was measured to be 2660 Pa (20 Torr). In comparison, in case a piping having the inner diameter of ¾ inch was employed and the pressure in the processing vessel 120 was set to be 66.6 Pa (0.5 Torr), the pressure in the source vessel 10 was 372 Pa (2.8 Torr).

Moreover, in case a piping having the inner diameter of ½ inch was employed and the pressure in the processing vessel 120 was set to be 133 Pa (1 Torr), the pressure in the source vessel 10 ranged from 1051 to 1596 Pa (7.9 to 12 Torr).

From the above test results, it can be seen that in case the source supply line 30 has the inner diameter of ¼ inch, the difference between the pressure in the processing vessel 120 and that in the source vessel 10 is, at least, greater than or equal to 1995 Pa (15 Torr), whereas in case the source supply line 30 has the inner diameter of ½ inch or ¾ inch, the difference is, at most, smaller than or equal to 1995 Pa (15 Torr), so that the pressure loss at the source supply line 30 is reduced.

Hereinafter, an exemplary film forming process, that was carried out for the purpose of comparing the film forming rate while varying the piping diameters, will be described.

First of all, as a comparative example, a W film was formed from W(CO)₆ utilizing the source supply line 30 comprised of a piping having an inner diameter of ¼ inch and a length of 2 m, by using the thermal CVD method. The temperature of the source vessel 10 was set to be 45° C., and the flow rate of the carrier gas was set to be 300 sccm (1 sccm represents the flow rate of a fluid with the volume of 1 cm³ at 0° C. and 1 atm). Further, the film forming process was carried out at the pressure (i.e., the pressure in the processing vessel 120) of 20.0 Pa (0.15 Torr) and at the substrate temperature of 450° C. As a result, the tungsten film was formed at the film forming speed of 10 Å/min, and the resistivity of the tungsten film obtained was 54 μΩcm.

In contrast, in case a piping having the inner diameter of ½ inch and the length of 2 m was employed for the source supply line 30, the tungsten film was formed at the film forming speed of 40 Å/min, and the resistivity of the tungsten film was 40 μΩcm.

Further, in case a piping having the inner diameter of ¾ inch and the length of 1 m was employed for the source supply line 30, the tungsten film was formed at the film forming speed of 300 Å/min, and the resistivity of the tungsten film was 45 μΩcm.

From the above working examples, it was confirmed that in case a piping having the inner diameter of, e.g., greater than or equal to ½ inch is employed for the source supply line 30 extending from the source vessel 10 to the processing vessel 120, the flow rate of the source gas substantially increases and the film forming rate is greatly improved.

### [EXAMPLE 2]

This Example was performed for the purpose of comparing the second embodiment of the present invention, described above, with the prior art illustrated in FIG. 5.

In this Example, pressure variances in the source vessel 10, which caused fluctuations in the flow rate of the source gas, were compared.

At first, using the conventional system shown in FIG. 5 as a comparative example, the mixed gas was made to flow through the pre-flow line 33′ before conducting the film forming process and then the pressure in the source vessel 10′ was measured by the pressure gauge 18′. Thereafter, by switching a flow path using the valve 26′, the mixed gas was provided into the source supply line 30′ which was connected to the processing vessel 120′, and then the pressure in the source vessel 10′ was measured by the pressure gauge 18′.

When the pre-flow line 33′ was activated, the pressure in the source vessel 10′ was 3990 Pa (30 Torr). However, when the source gas was introduced into the processing vessel 120′, the pressure in the source vessel 10′ was 1330 Pa (10 Torr), showing a considerable pressure difference therebetween. From these measurements, it was confirmed that, in the conventional system, the flow rate of the source gas fluctuates greatly during the film forming process.

On the other hand, when the pre-flow line 33 of the present invention, as shown in FIG. 3A, was used, it was possible to maintain the pressure in the source vessel 10 at 1330 Pa (10 Torr) both during the activation of the pre-flow line 33 and during the introduction of the source gas into the processing vessel 120. Accordingly, in accordance with the second embodiment of the present invention, it was possible to conduct the film forming process with a constant level of the source gas, i.e., without a fluctuation in the flow rate of the source gas.

As demonstrated above, in accordance with each embodiment of the present invention, due to the increase in the conductance of the source supply channel, it is possible to substantially increase the flow rate of the source gas being introduced into the film forming chamber. Further, since the pressure loss at the source supply channel (i.e., the difference between the pressure in the source vessel and that in the film forming chamber during the film forming process) is reduced due to the use of a larger diameter piping, it is possible to efficiently reduce the pressure in the source vessel during the film forming process. Furthermore, the reduction of the pressure loss at the source supply channel contributes to an increase in the amount of the source gas produced from the source material in the film forming chamber. As a result, the film forming rate is considerably improved, thereby greatly increasing the throughput.

In addition, by providing an additional turbo molecular pump at the pre-flow channel, it is possible to greatly reduce the difference between the pressure in the source vessel while the pre-flow channel is activated and that in the source vessel when the film forming process is performed. Accordingly, the flow rate of the source gas is further stabilized during the film forming process, thereby achieving a high-quality film forming process.

Moreover, since the pressure in the source vessel is efficiently reduced during the film forming process, even if a low vapor pressure source material is employed, it is possible to obtain a sufficient flow rate of the source gas.

While the invention has been shown and described with respect to the preferred embodiments, it will be understood by those skilled in the art that various changes and modifications may be made without departing from the spirit and scope of the invention as defined in the following claims.

1. A film forming apparatus comprising:
a source vessel for accommodating a source material used to generate a source gas;
a film forming chamber wherein a film forming process is performed on a semiconductor substrate;
a source supply channel for supplying the source gas from the source vessel to the film forming chamber;
a gas exhaust channel, having a vacuum pump system comprised of a turbo molecular pump and a dry pump, for exhausting the film forming chamber; and
a pre-flow channel branching off from the source supply channel and joining to the gas exhaust channel,
wherein a second turbo molecular pump is provided at the pre-flow channel.

2. A film forming apparatus comprising:
a source vessel for accommodating a source material used to generate a source gas;
a film forming chamber wherein a film forming process is performed on a semiconductor substrate;
a source supply channel for supplying the source gas from the source vessel to the film forming chamber;
a gas exhaust channel, having a vacuum pump system comprised of a turbo molecular pump and a dry pump, for exhausting the film forming chamber; and
a pre-flow channel branching off from the source supply channel and joining to the gas exhaust channel,
wherein the pre-flow channel joins to the gas exhaust channel at an upstream of the turbo molecular pump.

3. A film forming apparatus comprising:
a source vessel for accommodating a source material used to generate a source gas;
a film forming chamber wherein a film forming process is performed on a semiconductor substrate;
a source supply channel for supplying the source gas from the source vessel to the film forming chamber;
a gas exhaust channel, having a vacuum pump system comprised of a turbo molecular pump and a dry pump, for exhausting the film forming chamber; and
a pre-flow channel branching off from the source supply channel and joining to the gas exhaust channel,
wherein the piping diameter of the pre-flow channel is enlarged to reduce a pressure difference between the pressure in the source vessel during the activation of the pre-flow line and the pressure in the source vessel during the film forming process.

4. The film forming apparatus of any one of claims 1 to 3, wherein valves provided at the pre-flow channel and/or the source supply channel have a conductance Cv which is larger than or equal to 1.5.

5. The film forming apparatus of any one of claims 1 to 3, wherein the source supply channel is designed to maintain the difference between the pressure in the source vessel and that in the film forming chamber during the film forming process, to be smaller than 2000 Pa.

6. The film forming apparatus of any one of claims 1 to 3, wherein the source supply channel includes a piping having an inner diameter of greater than or equal to about 16 mm.

7. The film forming apparatus of any one of claims 1 to 3, wherein a source gas, generated from a source material having a vapor pressure lower than 133 Pa at a vaporization temperature, flows through the source supply channel.

8. The film forming apparatus of claim 7, wherein the source material is W(CO)₆.

9. The film forming apparatus of any one of claims 1 to 3, wherein the film forming chamber is maintained at a pressure lower than 665 Pa during the film forming process.

10. The film forming apparatus of any one of claims 1 to 3, wherein the source supply channel includes a piping with an inner diameter of greater than 6.4 mm.

11. The film forming apparatus of claim 10, wherein the source supply channel includes a piping having an inner diameter of greater than 6.4 mm over a range of, at least, 80% of the entire length thereof.
